(19) United States
(12) Patent Application Publication
(10) Pub. No.: US 2016/0014927 A1
(43) Pub. Date: Jan. 14, 2016

(54) HEAT DISSIPATING MODULE AND METHOD OF COMBINING THE SAME

(71) Applicant: DELTA ELECTRONICS, INC., Taoyuan County (TW)

(72) Inventors: Hung-Chuan CHEN, Taoyuan County (TW); Shih-Ching LIAO, Taoyuan County (TW)

(21) Appl. No.: 14/484,048

(22) Filed: Sep. 11, 2014

(30) Foreign Application Priority Data
Jul. 11, 2014 (TW) 103123889

(51) Int. Cl. H05K 7/20

(52) U.S. Cl. CPC H05K 7/2039

(57) ABSTRACT

In a heat dissipating module and a method of combining the heat dissipating module, the heat dissipating module includes a circuit board, a heat generating component, a heat dissipating element, and a surface mount layer. The circuit board has a through hole, and the heat generating component is corresponsive to the through hole and installed on the circuit board, and the heat dissipating element has a protruding embedding portion formed on the other side of the circuit board and embedded into the through hole. The surface mount layer is formed on a surface of the circuit board and the internal periphery of the through hole, and the heat generating component and heat dissipating element are combined with both surfaces of the circuit board respectively, and the heat generating component and the embedding portion are contacted with each other through the surface mount layer.

### FIELD OF THE INVENTION

The present invention relates to the heat dissipating technology of a surface mount device (SMD), and more particularly to a heat dissipating module and a method of combining the heat dissipating module with a circuit board and/or heat generating/dissipating components.

### BACKGROUND OF THE INVENTION

In general, the heat of most heat generating components including surface mount devices (SMD) such as transistors are dissipated by a heat sink or a heat dissipating element attached onto the top surface of the transistors. Since most transistors are made of plastic or an insulation material, therefore the thermal impedance of the transistors is relatively higher, and the heat dissipating effect of the aforementioned heat dissipating method is relatively lower. Some manufacturers cool the transistors or other heat generating components by increasing the heat dissipating surface area or the rotating speed of a fan, and thus incurring a higher cost.

In conventional surface mount technology (SMT) methods, the transistors or other heat generating components are mounted onto a side of a circuit board by the surface mount technology, and then a heat sink or a heat dissipating element is combined with the other side of the circuit board. In this method, the heat sink or heat dissipating element is separated from the heat generating components by the circuit board, or the heat sink or heat dissipating element is hardly in contact with the transistors or heat generating components, so that the thermal conduction performance is low. Obviously, the conventional method requires improvements.

In view of the foregoing drawbacks of the prior art, the inventor of the present invention based on years of experience in the related industry to conduct extensive researches and experiments and provided a feasible solution to overcome the drawbacks of the prior art.

### SUMMARY OF THE INVENTION

Therefore, it is a primary objective of the present invention to provide a heat dissipating module and a method of combining the heat dissipating module, wherein a heat generating component such as a transistor is installed on a circuit board and penetrated through a through hole, and a plate-shaped heat dissipating element is attached onto a surface which is configured to be back-to-back with a surface of the circuit board, and then the heat dissipating element is combined with the through hole by punching, so that the circuit board, the heat generating component and the heat dissipating element can be adhered and combined together by the surface mount technology (SMT) method, and the heat dissipating element is in contact with the heat generating component to provide a better heat dissipation performance to the heat generating component.

To achieve the aforementioned objective, the present invention provides a heat dissipating module, comprising: a circuit board, having at least one through hole penetrating through the circuit board; a heat generating component, corresponsive to the through hole, and disposed on a surface of the circuit board; a heat dissipating element, installed on the other surface of the circuit board, and having at least one embedding portion formed on the heat dissipating element, and the embedding portion in a protruding form being recessed into the through hole; and a surface mount layer, formed on the circuit board surface and at the internal periphery of the through hole, so that the heat generating component and the heat dissipating element can be combined with both surfaces of the circuit board respectively, and the heat generating component is in contact with the embedding portion through the surface mount layer.

To achieve the aforementioned objective, the present invention provides a heat dissipating module, comprising: a circuit board, having a first surface and a second surface, and at least one through hole formed on the circuit board and penetrating through the first surface and the second surface; a heat generating component, corresponsive to the through hole, and disposed on the first surface of the circuit board; a heat dissipating element, having a contact surface, a heat dissipating surface, and at least one embedding portion, and the embedding portion being recessed from the heat dissipating surface towards the contact surface and in a protruding form, so that the embedding portion is embedded into the through hole; and a surface mount layer, formed on the first and second surfaces and at the internal periphery of the through hole, so that the heat generating component and the heat dissipating element are combined with the first and second surfaces respectively, and the heat generating component and the embedding portion being in contact with each other through the surface mount layer.

To achieve the aforementioned objective, the present invention provides a method of combining the heat dissipating module, comprising the following steps:

(a) Prepare a circuit board, a heat generating component to be installed on the circuit board, and a heat dissipating element to be installed on the circuit board and configured to be back-to-back with the heat generating component.

(b) Punch a through hole through the circuit board, and align the through hole correspondingly between the heat generating component and the heat dissipating element.

(c) Form an embedding portion on the heat dissipating element and align the embedding portion with the through hole.

(d) Finally, combine the heat generating component and the heat dissipating element with the circuit board through a surface mount technology method, and the embedding portion is in contact with the heat generating component by surface mount technology.

### BRIEF DESCRIPTION OF THE DRAWINGS

FIG. 1 is a flow chart of a method of combining a heat dissipating module in accordance with the present invention;

FIG. 2 is an exploded view of a heat dissipating module in accordance with a first preferred embodiment of the present invention;

FIG. 3 is a perspective view of a heat dissipating module in accordance with the first preferred embodiment of the present invention;

FIG. 4 is a sectional view of a heat dissipating module in accordance with the first preferred embodiment of the present invention;

FIG. 5 is a sectional view of a heat dissipating module in accordance with a second preferred embodiment of the present invention;

FIG. 6 is a sectional view of a heat dissipating module in accordance with a third preferred embodiment of the present invention;

FIG. 7 is a sectional view of a heat dissipating module in accordance with a fourth preferred embodiment of the present invention;

FIG. 8 is a sectional view of a heat dissipating module in accordance with a fifth preferred embodiment of the present invention; and

FIG. 9 is a sectional view of a heat dissipating module in accordance with a sixth preferred embodiment of the present invention.

### DESCRIPTION OF THE PREFERRED EMBODIMENTS

The technical contents of the present invention will become apparent with the detailed description of preferred embodiments accompanied with the illustration of related drawings as follows. It is intended that the embodiments and figures disclosed herein are to be considered illustrative rather than restrictive.

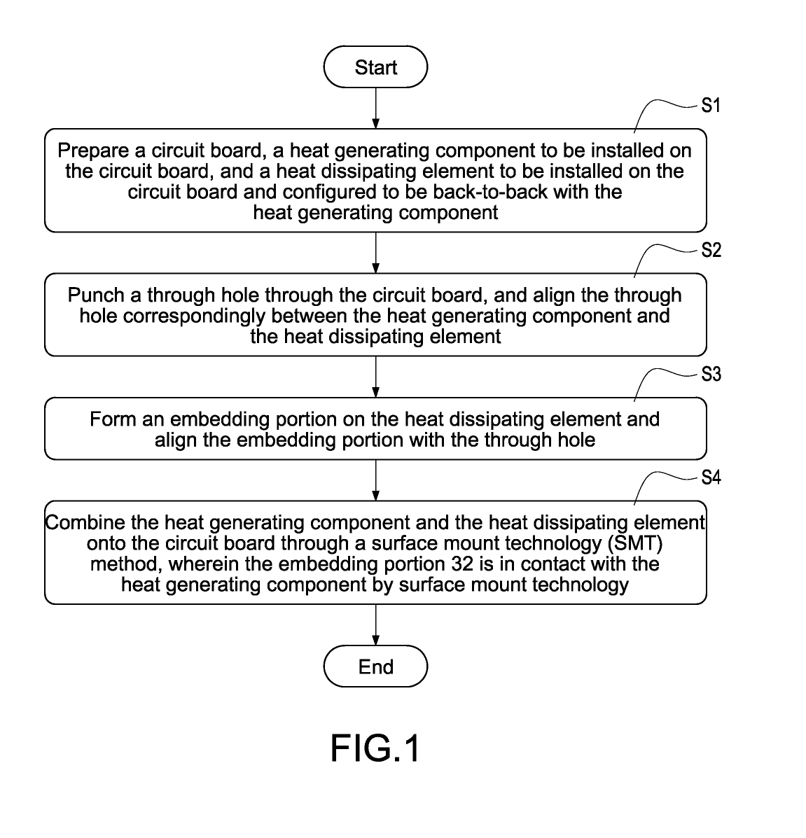

With reference to FIGS. 1 to 3 for a flow chart of a method of combining a heat dissipating module of the present invention, and an exploded view and a perspective view of the heat dissipating module in accordance with the first preferred embodiment of the present invention respectively, the method of combining the heat dissipating module (as shown in FIG. 1) comprises the following steps:

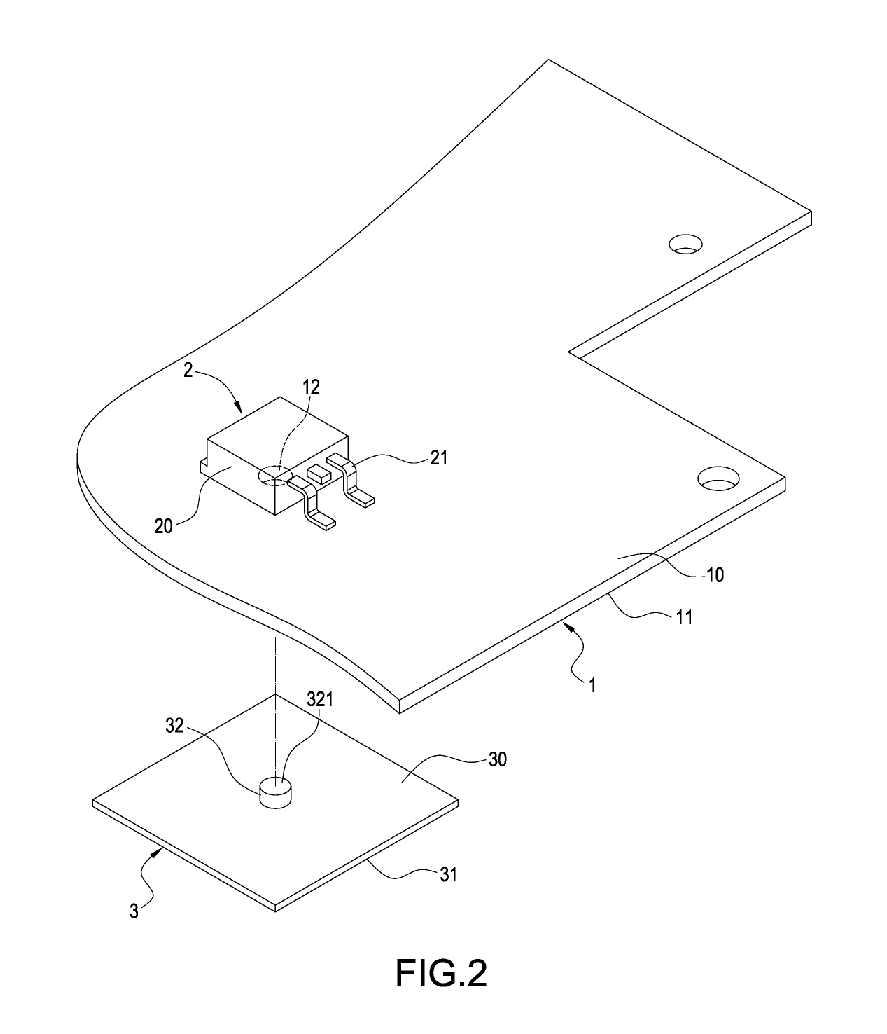

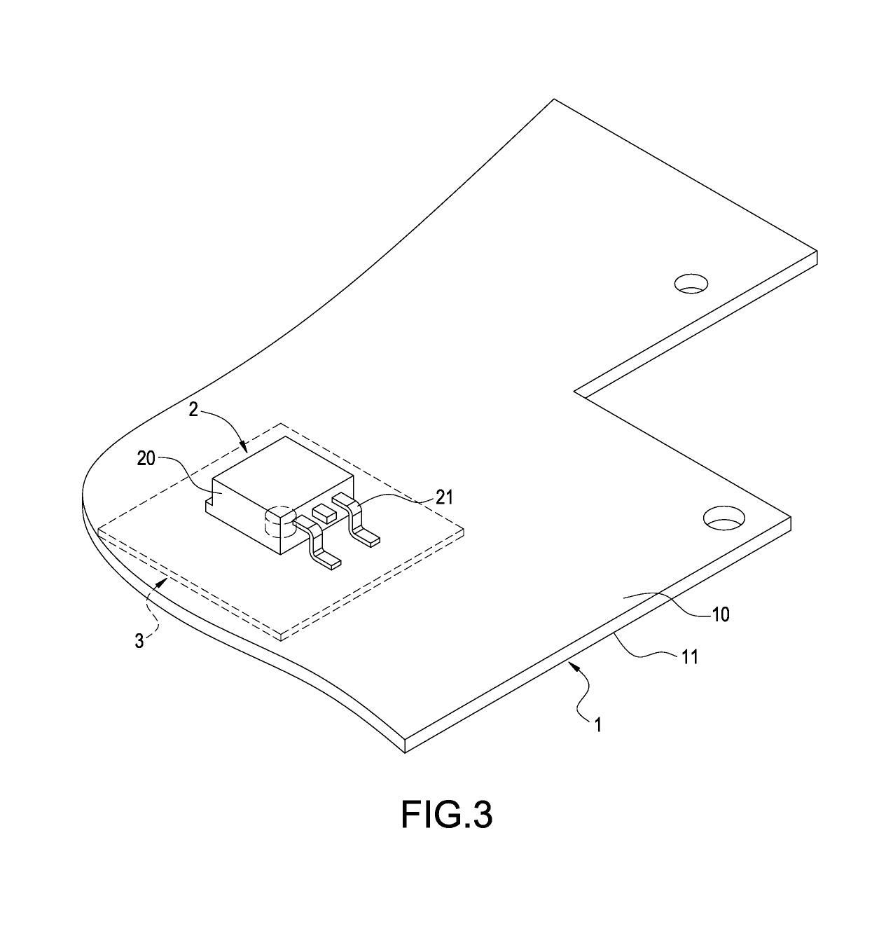

S1: Prepare a circuit board 1, a heat generating component 2 to be installed on the circuit board 1, and a heat dissipating element 3 to be installed on the circuit board 1 and configured to be back-to-back with the heat generating component 2. In FIGS. 2 and 3, the circuit board 1 has two surfaces which are named as a first surface 10 and a second surface 11 respectively in the preferred embodiment of the present invention, wherein the first surface 10 is provided for cladding a copper foil circuit thereon and installing the heat generating component 2; and the second surface 11 is configured to be back-to-back with the first surface 10 and provided for installing the heat dissipating element.

S2: Punch a through hole 12 through the circuit board 1, and align the through hole 12 correspondingly between the heat generating component 2 and the heat dissipating element 3. In FIGS. 2 and 3, the through hole 12 is formed by drilling or punching and penetrated through both surfaces (which are the first surface 10 and the second surface 11) of the circuit board 1, so that the heat generating component 2 and the heat dissipating element 3 installed on the circuit board 1 are interconnected through the through hole 12 (as shown in FIG. 3).

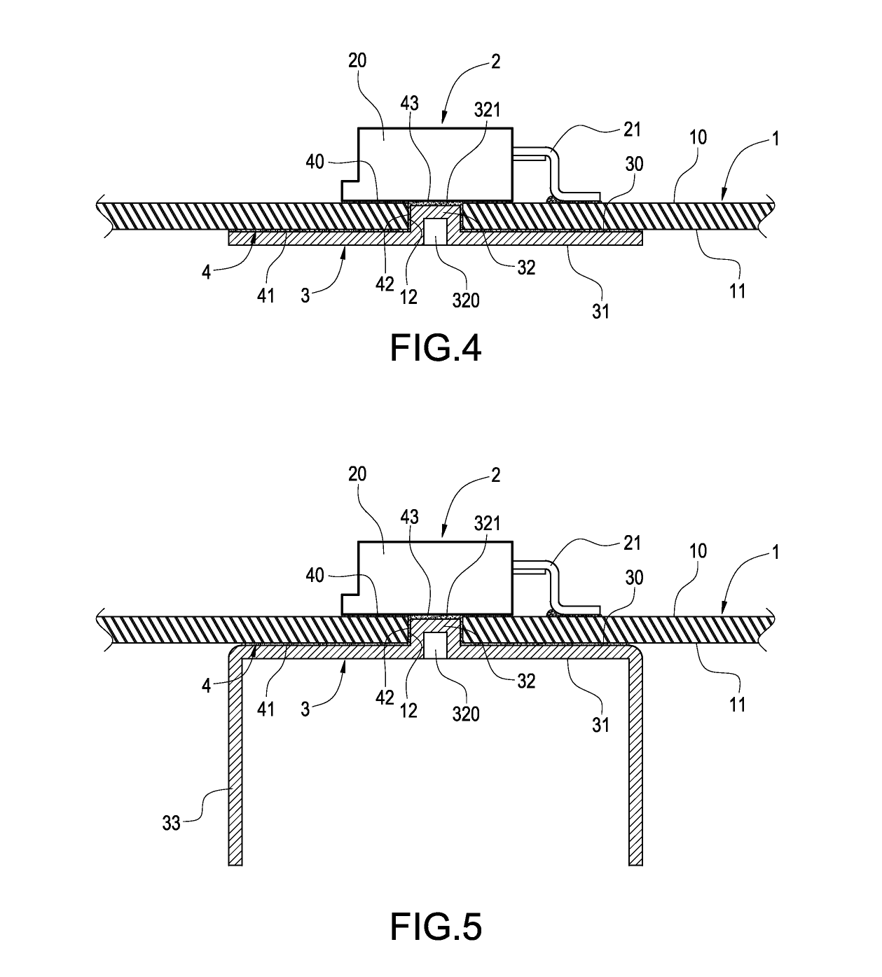

S3: Form an embedding portion 32 on the heat dissipating element 3 and align the embedding portion 32 with the through hole 12. In FIGS. 2 and 3, the heat dissipating element 3 of the preferred embodiment of the present invention is plate-shaped and has a contact surface 30 and a heat dissipating surface 31, and the contact surface 30 is disposed on the second surface 11 of the circuit board 1, and the embedding portion 32 as shown in FIG. 4 is recessed from the heat dissipating surface 31 towards the contact surface 30 to produce a protruding form, and a blind hole 320 may be formed by punching the heat dissipating surface 31 by a concave or convex punching process, so that the embedding portion 32 on the contact surface 30 is in a protruding form, and the embedding portion 32 is configured to be corresponsive to the through hole 12 and embedded into the through hole 12. In addition, the embedding portion 32 may have a top end 321, which is preferably a plane.

S4: Combine the heat generating component 2 and the heat dissipating element 3 onto the circuit board 1 through a surface mount technology (SMT) method, wherein the embedding portion 32 is in contact with the heat generating component 2 by surface mount technology. In FIG. 4, a surface mount layer 4 is formed on a surface of the circuit board 1 and at the internal periphery of the through hole 12. In this preferred embodiment of the present invention, the surface mount layer 4 includes a first mounting portion 40, a second mounting portion 41, a third mounting portion 42, and a fourth mounting portion 43, wherein the first mounting portion 40 is formed between the first surface 10 of the circuit board 1 and the heat generating component 2; the second mounting portion 41 is formed between the second surface 11 of the circuit board 1 and the contact surface 30 of the heat dissipating element 3; the third mounting portion 42 is formed at the internal periphery of the through hole 12 and coupled to the first and second mounting portions 40, 41; and the fourth mounting portion 43 is formed between the embedding portion 32 of the heat dissipating element 3 and the heat generating component 2, particularly between the top end 321 of the embedding portion 32 and the heat generating component 2 and coupled to the first and third mounting portions 40, 42.

In FIG. 4, the heat generating component 2 comprises a heat generating body 20, and a plurality of pins 21 extended from the heat generating body 20, and each pin 21 is combined with a copper foil circuit (not shown in the figure) on the circuit board 1 by the surface mount technology method. In the step S4 of the present invention, the heat generating body 20 of the heat generating component 2 and its pins 21 are combined with the first surface 10 of the circuit board 1 and the copper foil circuit (not shown in the figure) by the surface mount technology method, and then the contact surface 30 of the heat dissipating element 3 and its embedding portion 32 are combined with the second surface 11 of the circuit board 1 and the internal periphery of the through hole 12 by the surface mount technology method, so as to achieve the effect of combining the heat generating component 2 and the heat dissipating element 3 with the circuit board 1, and the embedding portion 32 is in contact with the bottom of the heat generating component 2 by surface mount technology. Particularly, if the top end 321 of the embedding portion 32 is a plane, the effect of contacting the bottom of the heat generating component 2 will be better. On the other hand, the contact surface 30 of the heat dissipating element 3 and its embedding portion 32 are combined with the second surface 11 of the circuit board 1 and the internal periphery of the through hole 12 by the surface mount technology method, and then the heat generating body 20 of the heat generating component 2 and its pins 21 are combined with the first surface 10 of the circuit board 1 and the copper foil circuit (not shown in the figure) by the surface mount technology method.

With the aforementioned assembly and structure, the heat dissipating module and the method of combining the heat dissipating module in accordance with the present invention are achieved.

With reference to FIG. 5 for a sectional view of a heat dissipating module in accordance with the second preferred embodiment of the present invention, the heat dissipating element 3 further includes at least one fin 33 substantially n-shaped and extended from the heat dissipating element 3, and the fins 33 are provided for increasing the heat dissipating surface area.

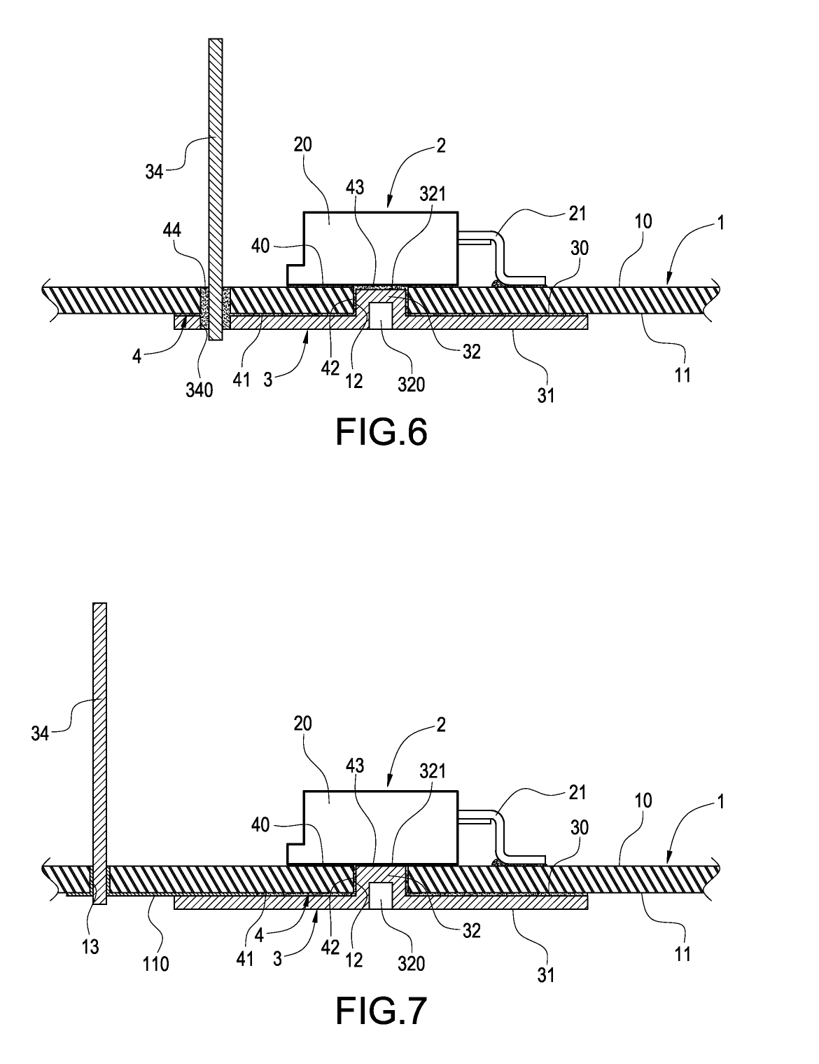

With reference to FIG. 6 for a sectional view of a heat dissipating module in accordance with the third preferred embodiment of the present invention, the heat dissipating element 3 includes a penetrating portion 340 disposed on a side of the heat dissipating element 3, and the circuit board 1 has a penetrating hole 13 corresponsive to the penetrating portion 340 for passing a fin 34 at the penetrating portion 340 and the penetrating hole 13, and a solder 44 such as a solder paste is used for the combination by the surface mount technology (SMT), and the fins 34 are erected and extended in a direction towards the first surface 10 of the circuit board 1.

With reference to FIG. 7 for a sectional view of a heat dissipating module in accordance with the fourth preferred embodiment of the present invention, the circuit board 1 has a thermal conducting layer 110 comprised of a copper foil and cladded onto the second surface 11, and the thermal conducting layer 110 is extended to the internal periphery of the penetrating hole 13 and provided for keeping the fins 34 that pass through the penetrating hole 13 to be in contact with the thermal conducting layer 110, and the heat dissipating element 3 is partially attached onto the thermal conducting layer 110, so that the contact surface 30 of the heat dissipating element 3 is in contact with the thermal conducting layer 110 to achieve the thermal transfer effect.

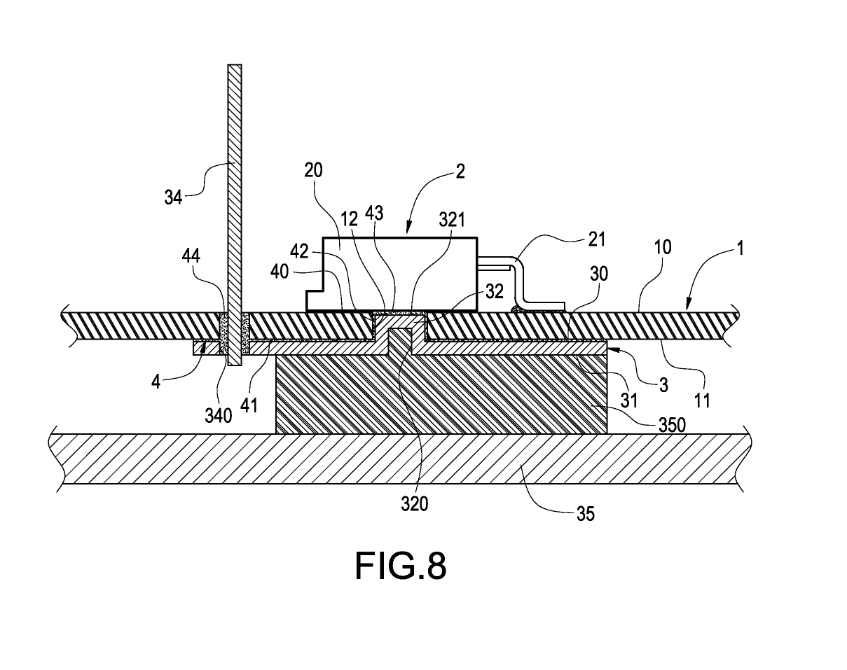

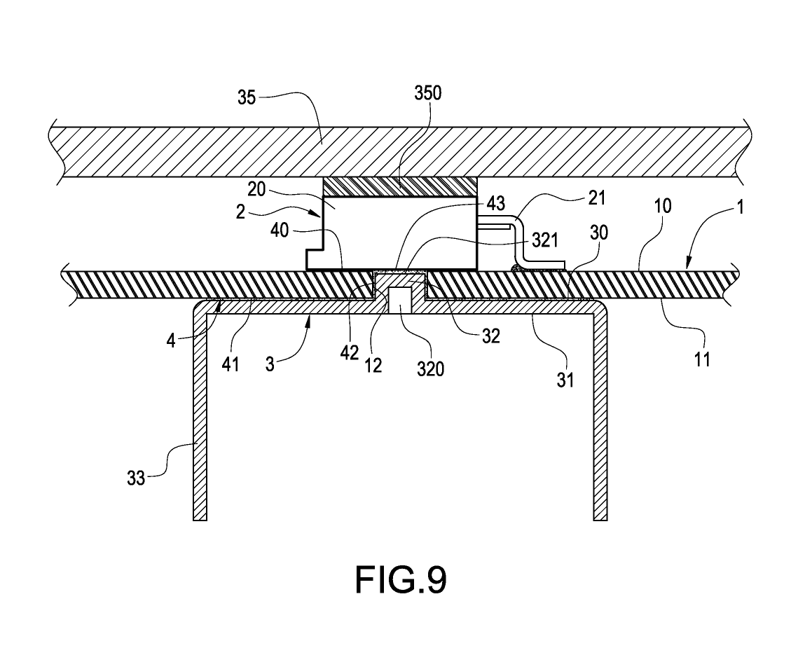

With reference to FIG. 8 for a sectional view of a heat dissipating module in accordance with the fifth preferred embodiment of the present invention, the heat dissipating element 3 further includes a thermal conducting element 350 attached onto the heat dissipating surface 30 of the heat dissipating element 3. In FIG. 9, the thermal conducting element 350 may also be attached onto the heat generating body 20 of the heat generating component 2 to keep the thermal conducting element 350 to be in contact with a part such as a casing 35 of an electronic product in order to transfer the heat to the outside of the casing 35, and a better heat dissipating effect is achieved by the external cool air having a relatively lower temperature.

In the heat dissipating module and the method of combining the heat dissipating module in accordance with the present invention, the circuit board 1, the heat generating component 2 and the heat dissipating element 3 are adhered and combined with each other by the surface mount technology (SMT) method, so that the heat dissipating element 2 is in contact with the heat generating component 1 through the embedding portion 32 to provide a better heat dissipating effect to the heat generating component 2, so as to simplify the installed heat dissipating components and reduce the cost of the heat dissipating components.

The present invention achieves the expected objectives and overcomes the drawbacks of the prior art, and the invention complies with patent application requirements, and is thus duly filed for patent application.

While the invention has been described by means of specific embodiments, numerous modifications and variations could be made thereto by those skilled in the art without departing from the scope and spirit of the invention set forth in the claims.

What is claimed is:

1. A heat dissipating module, comprising:
a circuit board, having at least one through hole penetrating through the circuit board;
a heat generating component, corresponsive to the through hole, and disposed on a surface of the circuit board;
a heat dissipating element, installed on the other surface of the circuit board, and having at least one embedding portion formed on the heat dissipating element, and the embedding portion in a protruding form being recessed into the through hole; and
a surface mount layer, formed on the circuit board surface and the internal periphery of the through hole, so that the heat generating component and the heat dissipating element are combined with both surfaces of the circuit board respectively, and the heat generating component in contact with the embedding portion through the surface mount layer.

2. The heat dissipating module of claim 1, wherein the heat dissipating element is substantially plate-shaped or n-shaped.

3. The heat dissipating module of claim 1, wherein the heat dissipating element has at least one fin extended therefrom.

4. The heat dissipating module of claim 1, wherein the heat dissipating element has a penetrating portion formed on a side of the heat dissipating element, and the circuit board has a penetrating hole formed thereon and corresponsive to the penetrating portion, and a fin is passed through and installed to the penetrating portion and the penetrating hole and combined with each other by a solder.

5. The heat dissipating module of claim 1, wherein the circuit board has a penetrating hole formed thereon, and a thermal conducting layer formed on the other surface of the circuit board and extended to the internal periphery of the penetrating hole, and the thermal conducting layer is in contact with a fin that passes through the penetrating hole, and the heat dissipating element is partially attached onto the thermal conducting layer.

6. The heat dissipating module of claim 3, wherein the fin is erected and extended in a direction towards a surface of the circuit board.

7. The heat dissipating module of claim 1, wherein the embedding portion has a top end which is a plane.

8. A heat dissipating module, comprising:
a circuit board, having a first surface and a second surface, and at least one through hole formed on the circuit board and penetrating through the first surface and the second surface;
a heat generating component, corresponsive to the through hole, and disposed on the first surface of the circuit board;
a heat dissipating element, having a contact surface, a heat dissipating surface, and at least one embedding portion, and the embedding portion being recessed from the heat dissipating surface towards the contact surface and in a protruding form, so that the embedding portion is embedded into the through hole; and
a surface mount layer, formed on the first and second surfaces and at the internal periphery of the through hole, so that the heat generating component and the heat dissipating element are combined with the first and second surfaces respectively, and the heat generating component and the embedding portion being in contact with each other through the surface mount layer.

9. The heat dissipating module of claim 8, wherein the heat dissipating element is substantially plate-shaped or n-shaped.

10. The heat dissipating module of claim 8, wherein the heat dissipating element further includes at least one fin extended therefrom.

11. The heat dissipating module of claim 8, wherein the heat dissipating element has a penetrating portion formed on a side of the heat dissipating element, and the circuit board has a penetrating hole formed thereon and corresponsive to the penetrating portion, and a fin is passed through the penetrating portion and the penetrating hole, and combined with each other by a solder.

12. The heat dissipating module of claim 8, wherein the circuit board has a penetrating hole formed thereon, and the second surface has a thermal conducting layer disposed thereon and extended to the internal periphery of the penetrating hole, and the thermal conducting layer is in contact with a fin that passes through the penetrating hole, and the heat dissipating element is partially attached onto the thermal conducting layer.

13. The heat dissipating module of claim 10, wherein the fin is erected and extended in a direction towards the first surface.

14. The heat dissipating module of claim 8, wherein the heat dissipating surface has a thermal conducting element attached thereon.

15. The heat dissipating module of claim 8, wherein the heat generating component is attached with a thermal conducting element.

16. The heat dissipating module of claim 8, wherein the embedding portion has a top end which is a plane.

17. The heat dissipating module of claim 8, wherein the surface mount layer further comprises a first mounting portion, a second mounting portion, a third mounting portion, and a fourth mounting portion, and the first mounting portion is formed between the first surface and the heat generating component, and the second mounting portion is formed between the second surface and the heat dissipating element, and the third mounting portion is formed at the internal periphery of the through hole, and the fourth mounting portion is formed between the embedding portion and the heat generating component.

18. The heat dissipating module of claim 17, wherein the third mounting portion is coupled to the first and second mounting portions, and the fourth mounting portion is coupled to the first and third mounting portions.

19. A method of combining a heat dissipating module, comprising the steps of:
(a) preparing a circuit board, a heat generating component to be installed on the circuit board, and a heat dissipating element to be installed on the circuit board and configured to be back-to-back with the heat generating component;
(b) punching a through hole through the circuit board, and aligning the through hole correspondingly between the heat generating component and the heat dissipating element;
(c) forming an embedding portion on the heat dissipating element and aligning the embedding portion with the through hole; and
(d) combining the heat generating component and the heat dissipating element with the circuit board by surface mount technology, and the embedding portion is in contact with the heat generating component by surface mount technology.

20. The method of combining a heat dissipating module according to claim 19, wherein in the step (d), the heat generating component is combined with the circuit board by the surface mount technology, and then the heat dissipating element is combined with the circuit board by the surface mount technology.

21. The method of combining a heat dissipating module according to claim 19, wherein in the step (d), the heat dissipating element is combined with the circuit board by the surface mount technology, and then the heat generating component is combined with the circuit board by the surface mount technology.
